(19) United States
(12) Patent Application Publication
(10) Pub. No.: US 2026/0329264 A1
(43) Pub. Date: Oct. 22, 2026

(54) METHODS AND SYSTEMS FOR OPERATING CHEMICAL PLANTS

(71) Applicant: BASF SE, Ludwigshafen am Rhein (DE)

(72) Inventors: Jan Philipp Herrmann, Ludwigshafen am Rhein (DE); Mihail Bogojeski, Berlin (DE)

(21) Appl. No.: 19/486,128

(22) PCT Filed: May 28, 2024
(86) PCT No.: PCT/IB2024/055152

§ 371 Date: Nov. 20, 2025

(30) Foreign Application Priority Data
May 31, 2023 (EP) 23176549.6

(51) Int. Cl. G05B 19/418; G06N 3/0455; G06N 3/08; H03M 7/30

(52) U.S. Cl. CPC G05B 19/41885; G06N 3/0455; G06N 3/08; H03M 7/6011

(57) ABSTRACT

A method for operating a chemical plant (1) implemented to run a batch process (BP) for producing a chemical prod-uct, wherein the batch process (BP) includes a plurality of process steps (P1-PN), the method comprises the steps of: receiving (S1) sensor data (SDQ) associated with at least one process step (PQ) of said batch process (BP); processing (S2) said sensor data (SDQ) according to a data driven model (DDCM) for generating a com pressed digital representation (SDQ′) of the sensor data (SDQ); determining (S3) a quality measure indicative of a physicochemical quality of the chemical product to be produced by the plant (1) and/or a performance indicator of the batch process as a function of the digital representation (SDQ′) of said received sensor data (SDQ); and generating (S4) plan operation data (CD) indicative for operating the chemical plant (1) as a function of the determined quality measure. A system (1) for producing a chemical product comprises a control unit (3) and controllable plant units (6, 7, 10) associated to batch process steps (P1-PN), wherein the control unit (3) is implemented to execute the method.

### TECHNICAL FIELD

This disclosure relates to methods and systems for operating chemical plants or systems that are, in particular, implemented to run a batch process. Aspects relate to batch process monitoring and assessing the performance of the batch process or a quality or a product manufactured by the batch process. This disclosure also relates to a computer-implemented method, computer program and computer-readable medium embodying the methods for controlling a chemical plant.

### BACKGROUND

In batch processing or batch plants, the production of multiple products occurs with the same set of equipment or processing units, for example a chemical or biological reactor. In batch processes, a sequence of batch process steps are performed, each using processing units or processing actions according to a batch process specification. Each processing step influences the next processing step and thereby the potential key performance parameter/quality. Therefore, at an early stage of the batch process, i.e., after executing only a part of the entire batch process. Due to the dependence between the processing steps this is very challenging.

Sometimes, batch processes are examined and assessed only on a laboratory scale. It is then desirable to predict how an industrial implementation of the respective batch process performs prior to building large-scale chemical plants. It is thus an object of the present disclosure to provide methods and systems for efficiently controlling chemical plants or designing chemical plants.

### SUMMARY

The subject matter of the enclosed claims addresses this object.

Accordingly, an aspect of this disclosure a method for operating a (chemical) plant implemented to run a batch process for producing a (chemical) product is provided, wherein the batch process includes a plurality of process steps, the method comprising:
receiving sensor data associated with at least one process step of said batch process;
processing said sensor data according to a data driven model for generating a compressed digital representation of the sensor data associated with the at least one process step;
determining a quality measure indicative of a physicochemical quality of the (chemical) product to be produced by the plant and/or a performance indicator of the batch process as a function of the digital representation of said received sensor data;
generating plant operation data indicative for operating the (chemical) plant based on the determined quality measure and/or the determined performance indicator; and outputting plant operation data.

### EMBODIMENTS

An example provides for a method for operating a chemical plant implemented to run a batch process for producing a chemical product. The batch process includes a plurality of—preferably sequential—process steps. A method of this aspect comprises the steps of:
receiving sensor data associated with at least one process step of said batch process;
processing said sensor data according to a data-driven model (DDCM) for generating a compressed digital representation of the sensor data associated with the at least one process step;
determining a quality measure indicative of a physicochemical quality of the chemical product to be produced by the plant and/or a performance indicator of the batch process as a function of the digital representation of said received sensor data;
generating plant operation data indicative for operating the chemical plant (e.g. as a function of the determined quality measure); and outputting the plant operation data.

Embodiments as presented above and below may enable process control in a reliable way at an early stage of a process, so that reliable and cost-efficient production may be achieved, waste production may be reduced (e.g. due to less rejected products), less resources may be needed or used, energy and/or time may be saved.

In embodiments, “operating the chemical plant” is to be interpreted as monitoring and/or controlling the (chemical) plant.

In particular, the step of determining as a function of the digital representation, includes decompressing the digital representation and/or deconstructing the digital representation of the at least one or process steps of the batch process.

The generated plant operation data is indicative for operating the (e.g. chemical) plant and may include information that facilitates running the batch process with the (chemical) plant. In embodiments the plant operation data includes control data for the (chemical) plant and/or monitoring data for the (chemical) plant. The plant operation data may be indicative for operating the (chemical) plant and may be based on the determined quality measure and/or the determined performance indicator. For instance, a warning may be triggered if the determined quality measure is above or below a threshold. Plant operation data may also be determined by: processing the sensor data and the determined quality measure (and/or the determined performance indicator) according to the data-driven model for generating a compressed digital representation of the sensor data and the determined quality measure (and/or the determined performance indicator); and determining (further) batch process parameters e.g. for adjusting the batch process or further (not yet performed) batch process steps based on the compressed digital representation of the sensor data and the determined quality measure (and/or the determined performance indicator), e.g. in a similar fashion as the quality measure and/or performance indicator was obtained. Such (further) batch process parameters may be or be part of the plant operation data. For instance, it may allow to reconstruct certain batch process steps from knowledge of other batch process steps, so that e.g. the determined or generated target variable such as the quality measure may be fed back into the data-driven model, e.g. encoded together with the sensor data, so to determine, e.g. via decoding, how the (further) batch process may be adapted. If for instance it is determined that a (future or further) batch process parameter, such as a temperature should be lower than previously set for the respective batch process step, the plant operation data my include an operating instruction to lower the respective batch process parameter, in this example e.g. by lowering the heat by a certain temperature. The plant operation data may be output to an operator or driver of the plant e.g. via a user interface, so that the operator or driver may take suitable action. However, the plant operation data may also be output to a process for automatically—based on the plant operation data—operate the plant, e.g. adjust batch process parameters of further batch steps. Plant operation data obtained may be stored in a (non-transient and/or tangible) computer readable storage medium.

The enclosed methods and systems allow to determine or predict the performance of a batch process or product manufactured at an early stage of the batch process, i.e., after executing only a part of the entire batch process. This is due to the flexible digital representation based on a data driven model containing information on the interaction and interdependencies of the process steps and/or intermediate products or ingredients of the batch process, e.g. through a machine learning history.

Additionally, or alternatively, the step of determining may include predicting, calculating, computing or determining a performance indicator of a subset of the plurality of sequential batch process steps, in particular of one of the batch process steps, or a quality measure relating to an intermediate product, e.g., associated to one process step. It is understood that a batch process step in terms of this disclosure includes an action or use of a processing unit and can be characterized by a set of characterizing data (which may be batch process step parameters). One example for characterizing data are sensor data, for example relating to an identifier for a chemical substance, a geometry, a physicochemical property of a processing unit or medium, analytic properties of a chemical pre-, intermediate or end product, dimensions of a processing unit, a flow, a time period, a temperature (gradient) or other observables that are measurable by a technical device or parameters that technically define an entity involved in the respective batch process. A performance indicator may include data relative to working/operating points or statuses of the chemical plant according to a scale or preset statuses, information relating to other batch processes, facilities and/or chemical plants. The plant operation data, for example, be used to extrapolate the monitored plant behavior and predict a behavior of another plant.

In embodiments of the method, at least one of the steps of operating the chemical plant as a function of the control data, and/or comparing said determined quality measure and/or performance indicator with a target quality or performance is carried out.

Deploying a data-driven model to generate a compressed digital representation of the sensor data that can be seen as parameterizing a respective batch process step or a measurable property of an intermediate or the end product of the batch process allows for an efficient assessment of the quality and performance of the controlled chemical plant.

In a compressed digital representation of the sensor data, data processing can be executed in a more efficient fashion than using conventional simulation algorithms. The digital representation allows for a continuous and efficient monitoring of the batch process. Connecting and processing sensor data according to the data-driven model also allows for designing the actual chemical plant that is suitable to run the batch process prior to performing large-scale experiments with the plant's actual components.

The data-driven model (DDCM) may be configured to capture non-linear relations between batch process parameters such as between batch process parameters characterizing an initial resource like a substrate and a quality measure or performance indicator of the batch process. The data-driven model may be or comprise an encoder of a variational autoencoder, for instance an encoder of a multimodal variational autoencoder (MVAE), which may comprise (sub-)encoders for each mode. A data-driven model configured to capture non-linear relations may allow to model complex tasks such as upscaling production from laboratory scale to production scale or setting up production at a different plant having different conditions, which may not be possible with simpler linear models such as regression-based models, but at the same time may save resources compared to e.g. complex simulations. Also using an encoder of an autoencoder may result in a compressed digital representation, such as a latent space. For example if the data-driven model is an encoder of an autoencoder it may generate a compressed digital representation, which is indicative of said non-linear relations. A quality measure may then be determined e.g. by using a decoder of said autoencoder e.g. as a second or further data-driven model.

A (first) data-driven model and second data-driven model may be part of the same overall architecture, e.g. a (first) data-driven model may be the encoder of a variational autoencoder and a second data-driven model may be the decoder of the variational autoencoder. The data-driven model may be generative, in that it e.g. may be configured to generate or reconstruct (new) samples of data (e.g. batch process parameters) from the compressed digital representation of said data. Alternatively or additionally a data-driven model may be or comprise a Generative Adversarial Network (GAN) or a multimodal GAN.

For instance, when transitioning from a laboratory setting to a production environment, there are various factors and variables that may interact in complex and non-linear ways, which the data-driven model may capture in the compressed digital representation when trained with data from both environments. As an example, in a laboratory environment, experiments may be conducted with controlled conditions, which may not be present for the upscaled production environment. There may be changes in equipment, operating conditions, material properties, and process dynamics.

A (variational) autoencoder may comprise at least one encoder, which may comprise a neural network such as a feed-forward neural network. The at least one encoder may encode input data, such as sensor data associated with at least one process step of a batch process, into the compressed digital representation. For encoding the sensor data, batch process parameters that do not correspond to sensor data, i.e. that are not measured or unavailable as well as target variables such as a quality measure and/or performance indicator, may be set to zero, which may allow the encoder to treat them as missing. The compressed digital representation of the sensor data may have the form of a probability distribution, e.g. a Gaussian having a mean and standard deviation. The probability distribution in the compressed digital representation may be sampled, which may allow to generate output data such as the quality measure and/or the performance indicator, e.g. by using at least one decoder of the autoencoder. A variational autoencoder may comprise at least one decoder, which may comprise a neural network such as a feed-forward neural network. Using an autoencoder may allow for using relatively small training data sets compared to other generative models, for instance good prediction performance may be reached with 1500 to 2000 training data sets, which is comparable to the data needed for regression.

A Multimodal Variational Autoencoder (MVAE) may allow to handle input from multiple different data modalities, for instance each modality may represent a step of a batch process. The MVAE may comprise at least one encoder for each modality, for instance a feed-forward neural network. Please note the encoders for the modalities may together be referred to simply as the encoder or encoder part of the MVAE herein. The encoder in a Multimodal Variational Autoencoder (MVAE) may encode or transform the input data, such as sensor data into a compressed digital representation such as a (lower-dimensional, i.e. having a lower dimension than the sensor data space) latent space. As described the encoder of an MVAE may comprise several sub-encoders, each designed to process a different data modality. For example, for the batch process, there may be one (sub-)encoder for each batch process step. Each sub-encoder may be a neural network that determines, based on input data from its respective modality, a mean vector and a standard deviation vector that may define e.g. a (multivariate) Gaussian distribution in the compressed digital representation or latent space, which may allow the MVAE to generate (new) samples of data. The (sub-)encoders may process input data from their respective modalities and the encoder of the MVAE may combine the processed input data from the respective modalities to generate a (shared) compressed digital representation or latent space, which a decoder may use to generate new instances of data. The combination may e.g. be calculating the product of the individual distributions obtained by processing the input data from the respective modalities by the (sub-)encoders. The decoder of the MVAE may also comprise (sub-)decoders that may be configured to generate data for the respective modalities, e.g. for a specific batch process step. The decoder of the MVAE may sample from the compressed digital representation. The (sub-)decoders may obtain a sample or a point from the compressed digital representation and generate output data, e.g. a reconstruction of the input data in the respective modality. By decoding the compressed digital representation into the different modalities, the MVAE may be capable of generating output data that is consistent across all modalities. The MVAE may also be used for cross-modal generation tasks, which may allow to generate data in one modality given data in another modality. By generating a (shared) compressed digital representation for the different modalities, the MVAE may leverage information from all modalities to improve its performance. It may also handle scenarios where some modalities are missing by using the information from the other modalities to generate output data for the missing modalities. A modality may also be referred to as a mode herein.

During the decoding phase, the MVAE may decode the (shared) digital representation back into any of the given modalities. This may allow that using input data from one modality, output data in another modality may be generated. Plant operations data may be determined based on the compressed digital representation, e.g. by using a decoder of said autoencoder to generate batch process step parameters and including them in the plant operation data as instructions for implementing or tuning or adapting the batch process or a respective batch process step on the plant or another plan.

Batch process step parameters may be or be indicative of a chemophysical property of the process, e.g. a temperature or temperature gradient at which the corresponding batch process step is performed, a flow, speed at which the batch process step or parts of the batch process step are performed, a time period e.g. used for the batch process step, a physicochemical property of a processing unit or medium used, a geometry or dimensions e.g. of the processing unit or part of the processing unit performing the batch process step, or other observables that are measurable by a suitable sensor measuring sensor data or that are analytically derivable from said sensor data. A batch process step parameter may also be or be indicative of a property of an initial resource, pre-, intermediate product used in the batch process step or an end-product of the batch process step (which may correspond to a quality measure or performance indicator), e.g. an identifier for a chemical substance, analytic properties of a chemical pre-, intermediate or end product. Such measurable batch process step parameters may correspond to or be associated with sensor data. It is noted that target variables such as a quality measure and/or a performance indicator—at least if measurable using sensors—may be considered batch process step parameters which may be associated with e.g. the last step of the batch process, in that case e.g. a compressed digital representation of (i) a quality measure indicative of a physicochemical quality of the (chemical) product to be produced by the plant and/or a performance indicator of the batch process and (ii) the batch process step parameters of at least two process steps including said at least one process step may be a compressed digital representation of the batch process step parameters of at least two process steps including said (measured) at least one process step and the process step including the quality measure and/or performance indicator.

The compressed digital representation may be or comprise a latent space of an autoencoder or a GAN. It may capture non-linear relations between the data used for training such as sensor data and a quality of a product produced by the plant. Determining or generating a compressed digital representation may be trained by using training data from a plant or a laboratory including both the process step parameters and any target variable such as a quality measure or a performance indictor. Then, when measurements are performed e.g. using sensors of the plant or sensors associated with the part of the plant where a certain batch process step is carried out, the measurement data or sensor data may be processed (e.g. compressed or encoded) into a compressed representation of the (measured) sensor data. The compressed digital representation may then be used to determine (e.g. generate) the data that is not part of the (measured) sensor data, such as process parameters of other or future batch process steps, target variable such as the quality measure of the product to be produced or a performance indicator. These may be output e.g. to a plant operator, who may e.g. take suitable action to adjust the production process. Utilizing such a compressed digital representation may allow to capture the relations between batch process parameters of (essentially) the whole batch process and any target variables or other variables of interest, such as location specific variables or modifications. The compressed digital representation may hence be a compressed digital representation of the complete production process implemented in the plant. Hence, an omitted variable bias—as may e.g. be present in projection techniques—may be reduced or avoided, allowing for a higher prediction accuracy even at an early stage of the batch production process, e.g. reliable results may be obtained after just one batch process step allowing for early adjustments of the process, so that e.g. a more reliable and cost-efficient production may be achieved, waste production may be reduced (e.g. due to less rejected products), less resources may be needed or used, energy and/or time may be saved etc. Using a compressed digital representation of the sensor data may allow for a reliable and efficient production process. Further it may allow to reconstruct certain batch process steps from knowledge of other batch process steps, so that e.g. the determined or generated target variable such as the quality measure or may be fed back into the data-driven model, e.g. encoded together with the sensor data, so to determine, e.g. via decoding, how the (further) batch process may be adapted.

The compressed digital representation may be understood as generative, e.g. it may contain a probability distribution of the input data, from which a (new) instance of data may be sampled or generated. The probability distribution according to the different variables may be combined by a product of experts, in case of a MVAE the encoding of each mode μ_i and σ_i may be regarded as an expert. The sampling or generation may be non-deterministic. The compressed digital representation may be a latent space, which may be configured to capture the structure of the input data. New data may be sampled or generated from the latent space by transforming a sample taken from the latent space back into the (higher dimensional) input data space, in particular regardless of the process step. Input data of each process step may be reconstructed or generated from a sample.

According to an example embodiment, each process step being associated with a set of batch process step parameters, and the sensor data corresponding to at least one batch process parameter associated with the at least one process step, wherein processing (S2) said sensor data (SDQ) according to the data driven model (DDCM) for generating a compressed digital representation (SDQ′) is or comprises;
obtaining (S2) the compressed digital representation of the sensor data (SDQ) associated with the at least one process step (PQ) using the data-driven model (DDCM), the data driven model having been trained to generate a compressed digital representation of (i) a quality measure indicative of a physicochemical quality of the (chemical) product to be produced by the plant (1) and/or a performance indicator of the batch process (BP) and (ii) the batch process step parameters of at least two (preferably all) process steps including said at least one process step.

According to an example embodiment, determining (S3) the quality measure and/or the performance indicator is or comprises generating (S3) the quality measure and/or the performance indicator based on the compressed digital representation using a second data driven model, the second data driven model having been trained to generate the quality measure and/or the performance indicator from the compressed digital representation of (i) the quality measure indicative of a physicochemical quality of the (chemical) product to be produced by the plant (1) and/or the performance indicator of the batch process (BP) and (ii) the batch process step parameters of at least two (preferably all) process steps including said at least one process step; and wherein determining (S4) plant operation data (CD) is based on the generated quality measure and/or the generated performance indicator.

According to an example embodiment, the data driven model comprises an encoder of an autoencoder, and the second data driven model comprises a decoder of the autoencoder, wherein the encoder is trained to encode (i) the quality measure indicative of a physicochemical quality of the (chemical) product to be produced by the plant (1) and/or the performance indicator of the batch process (BP) and (ii) the batch process step parameters of at least two process steps including said at least one process step into the compressed digital representation and the decoder is respectively trained to decode (i) the quality measure indicative of a physicochemical quality of the (chemical) product to be produced by the plant (1) and/or the performance indicator of the batch process (BP) and (ii) the batch process step parameters of at least two process steps including said at least one process step from the compressed digital representation.

According to an example embodiment, the data-driven model is multi-modal, wherein each process step of the batch process corresponds to a mode of the multimodal data-driven model and, in particular at least one mode corresponds to the quality measure indicative of a physicochemical quality of the (chemical) product to be produced by the plant and/or the performance indicator of the batch process. The at least one mode corresponding to the quality measure indicative of a physicochemical quality of the (chemical) product to be produced by the plant and/or the performance indicator of the batch process may be a mode corresponding to a batch process step, in particular the last step of the batch process, or it may be a further mode particularly configured for the quality measure and/or the performance indicator. Having a certain mode for the quality measure and/or the performance indicator may be advantageous in that it may increase adaptability, e.g. when a performance indicator e.g. a quantifiable metric such as a key-performance indicator (KPI) is to be changed (e.g. yield, quality rate, cycle time, downtime, waste), and may increase the generation accuracy of predicted quality measures and/or performance indicators, e.g. due to a dedicated (sub-)decoder being associated with decoding the particular mode.

According to an example embodiment, the autoencoder is a multimodal variational autoencoder, wherein each process step of the batch process corresponds to a mode of the multimodal variational autoencoder (MVAE) and at least one further mode corresponds to the quality measure indicative of a physicochemical quality of the (chemical) product to be produced by the plant and/or the performance indicator of the batch process (BP).

Utilizing a multimodal approach, such as in a MVAE or multimodal GAN may allow for closely mapping or modeling the physical structure of the batch process and hence may allow for adapting the batch process rather easier, e.g. when a new production step needs to be included, so to enhance the production process.

Further it may allow to reconstruct certain batch process steps from knowledge of other batch process steps, so that e.g. the determined or generated target variable such as the quality measure or may be fed back into the model, e.g. encoded together with the sensor data, so to determine how the batch process may be adapted.

According to an example embodiment, at least one further mode corresponds to the location of the plant or a characteristic of the plant.

This may further enhance the production process and may enhance flexibility e.g. it may enhance the applicability to decode using a decoder trained on data from a plant or laboratory at one location and e.g. only sparse training data on the plant, the process parameters for the plant at another location, i.e. rendering it easier and less cost-intensive to transform production from one plant to another or the upscale from laboratory to production.

According to an example embodiment, the data driven model having further been trained to generate the compressed digital representation of (i) a quality measure indicative of a physicochemical quality of the (chemical) product to be produced by the plant (1) as produced by another plant and/or a performance indicator of the batch process (BP) implemented on the other plant and (ii) the batch process step parameters of at least two process steps implemented on the other plant including said at least one process step; and wherein
the second data driven model having been trained to generate the quality measure and/or the performance indicator from the compressed digital representation of (i) the quality measure indicative of a physicochemical quality of the (chemical) product to be produced by the plant (1) as produced by the other plant and/or the performance indicator of the batch process (BP) implemented on the other plant and (ii) the batch process step parameters of at least two process steps implemented on the other plant including said at least one process step.

This may allow to train the data-driven model primarily on one plant, e.g. a laboratory or research scale plant, and e.g. fine-or pre-tune it with less data from the plant that is to produce the (chemical) product, so data-driven model trained on one plant may be transferred for usage with another plant, which may enhance productivity at an early stage of plant operation.

According to an example embodiment, the batch process implemented on the plant (1) has at least one additional process step then the batch process implemented on the other plant, and wherein the method further comprises:
determining at least one process parameter of the at least one additional process step using the second data driven model; and
providing the at least one process parameter, e.g. to a user, such as a plant operator, via a (graphical) user interface, the plant operation data may comprise the at least one process parameter.

According to one aspect of the method, the data-driven model includes a multimodal variational autoencoder (MVAE), wherein the MVAE is implemented to receive input mode data and to output reconstructed mode data. A multimodal variational autoencoder allows handling data for multiple modalities and combining those into a single digital representation. The digital representation is also called latent space representation. One may contemplate of alternative models, e.g. a transformer model as a DDCM.

The compressed digital representation of the sensor data in the latent space requires a less amount of data with respect to a complete description including all measurable properties and characteristics of the various batch process steps according to the batch process specification and acquired sensor data. Hence, using an MVAE reduces the amount of required computational and memory resources to process and control a (chemical) plant. An encoder of a suitable MVAE can be considered a data-driven (compression) model as mentioned above. A decoder of the MVAE may be considered a second or generating data-driven model.

Preferably, the DDCM is implemented to receive input mode data and to output reconstructed mode data. In terms of the MVAE mode data refers to modalities and each modality or mode has an associated data set format. For example, a set of sensor data used to characterize an ingredient used during the batch process can be seen as one modality. Another modality may be a specification of a batch process step, e.g. in terms of pressure and temperature values during execution of a batch process step. One can contemplate of various types of modalities in connection with batch process steps. In embodiments, respective mode data for one modality is given as a set of variables in a predefined format for the respective mode/modality. Input mode data thus may correspond to a sensor data set. The format may be a vector, tensor or other computer readable and processible data structure. A modality may correspond to a physicochemical parameter.

In an embodiment of the method, each batch process step of the batch process is associated to one respective mode or modality. Then, said input mode data for a respective mode comprises the sensor data associated to the at least one batch process step being associated to the respective mode. Said output mode data for the respective mode then comprises reconstructed sensor data associated to the at least one batch process step being associated to the respective mode.

In an MVAE environment, a number of modalities is received in feature space as separate mode data, or sensor data sets respectively, and output as reconstructed modes, wherein an information loss may occur. The latter is preferably reduced and minimized when setting up the MVAE. The MVAE provides for a latent space representation or compressed digital representation of the received sensor data sets from the various process steps.

In embodiments, the DDCM has a predetermined number of modalities corresponding to the number of batch process steps. Then, the method further comprises inputting input mode data for a first set of modes including a first number of modes; and outputting reconstructed mode data for a second set of modes including a second number of modes. The first number of modes is preferably less than the second number of modes.

If there are more modes output in reconstructed space than mode data is input in the feature space, the additional modes with respect to the input modality number can be considered forecasts or predictions of certain modes. In particular, if the batch process includes a sequence of batch process steps, the used DDCM is implemented to process mode data sets for all modalities, i.e., all batch process steps. In order to predict, for example, a late process step outcome, “a target mode”, one may input sensor data or mode data only relating to process steps that are executed prior to the target mode or process step. Hence, the method allows to predict feature sensor data and thus the quality or performance of the batch process to be implemented in terms of the controlled system. As a result, the control data for future process steps may be adapted as a function of received input mode data.

In embodiments of the method, the second set of modes includes at least one mode associated to a batch process step that is carried out later than the batch process steps associated with the modes of the first set of modes.

In embodiments, the method includes training the DDCM using training data sets generated by monitoring a plurality of parameters of the batch process for generating sensor data indicative of respective batch process steps. The MVAE may be implemented including artificial neural networks that are trained with the training data sets. For example, large-scale or laboratory experiments representing the batch process steps may be used to generate training data sets. For example, variants of the batch processes include a laboratory set-up for the batch process systems having different production capacities for the chemical product to be produced, different plant scales, different chemical plants at different locations or parameters characterizing ingredients from different suppliers and the like.

The method may include measuring batch process parameters indicative of physicochemical properties of ingredients in terms of sensor data and/or characteristics of the batch process steps, and clustering said sensor data into clusters wherein each cluster is assigned to one batch process step and/or a mode of the MVAE/DDCM. A cluster may comprise a set of sensor data in a predetermined format. Treating the batch process steps as modes or modalities in terms of an MVAE as a data-driven compression model has the advantage that modes or process steps that are not available as input mode data in feature space can be reconstructed in reconstruction space. The MVAE provides a complete digital representation in latent space for the entirety of sensor data, that is frontloaded in terms of modes.

In embodiments of the method, the MVAE comprises a plurality of artificial neural networks (ANNs) as encoders for receiving mode input data in feature space. Each encoder is assigned to one input mode, and at least one encoder is configured as a feed-forward network, a convolutional network or a long short-term neural network. One may use different ANN types for different modalities, thereby improving a loss function of the MVAE.

In embodiments of the method, the DDCM has at least one further modality indicative of a location of the chemical plant and/or size of the chemical plant. For example, using the location of the chemical plant to be controlled as a modality allows for taking into account an impact of the location on the production of the chemical product. For example, a plant in Europe may require different configurations than a plant in the United States, even though if the batch process specification remains the same or similar. The location, for example, may be regarded as sensor data.

In embodiments, the method includes the step of predicting a quality measure and/or performance indicator for a selected batch process step based on sensor data associated with another process step of said batch process, wherein the other process step precedes the selected process step. The method preferably includes the step of generating the control data as a function of the predicted quality measure and/or performance indicator. Predicting may include reconstructing sensor data associated to the selected batch process step.

The method allows to provide an early indication of a quality issue when the batch process is initiated. The batch process may then be adapted or controlled in order to improve the quality or performance. This improves the yield and output of the respective plant. On the other hand, stopping a defective batch process saves resources and reduces wastes. The presented method also allows to scale a batch process set-up, for example from laboratory scale or experimental scale to a large industrial plant. This is because the scale may be used as a modality so that the DDCM may output reconstructed mode data that is associated to another scale with respect to scale of the input feature space modality data.

In embodiments of the method, the batch process includes a plurality of sequential process steps including a first process step and a last process step. Each batch process can be controlled as a function of control parameters that are implemented by the control data. The method preferably comprises adapting the control parameters of the selected batch process step as a function of the predicted quality measure and/or a predicted performance indicator.

The method allows for an efficient and reliable control of a batch process and thus the production of a chemical product.

In alternative aspects the step of generating control data is replaced by generating alternative batch process specification as a function of the quality measure and/or the performance indicator. In embodiments, the to define a design of a chemical plant suitable for implementing the batch process. The design may include a list of control, sensor and/or process units and their configuration.

According to another aspect, a system for producing a chemical product is disclosed. The system includes a control unit and controllable plant or processing units that are associated to batch process steps. A control unit is implemented to control the plant units according to the aspects or embodiments of the method disclosed above or below with respect to examples of this disclosure.

According to a further aspect, a computer-readable medium storing computer program instructions, wherein the computer program instructions, when executed by a control unit and/or processing unit according to aspects or embodiments disclosed above or below with respect to specific examples, cause the control unit and/or processing unit to perform operations comprising the method according to the aspects or embodiments disclosed above or below. The computer-readable medium is, in particular, a non-transitory computer-readable medium.

In embodiments, a computer-program or computer-program product comprises a program code for executing the above-described methods and functions by a computerized control unit when run on at least one computerized unit, in particular when run on the control unit of a chemical plant. A computer program product, such as a computer program means, may be embodied as a memory card, USB stick, CD-ROM, DVD or as a file which may be downloaded from a server in a network. For example, such a file may be provided by transferring the file comprising the computer program product from a wireless communication network.

Further, a system is provided for producing a (chemical) product comprising a control unit and controllable plant units associated to batch process steps, wherein the control unit is implemented to execute the method as described above or below.

Further, an apparatus is provided comprising respective means for carrying out or performing the steps of the method as described above or below.

Further, an apparatus is provided comprising at least one processor and at least one memory storing instructions that, when executed by the at least one processor, cause the apparatus at least to carry out the steps of the method as described above or below.

Further, plant operation data obtained by the method as described above or below or the apparatus as described above or below is provided.

Further, a computer program is provided comprising instructions for performing at least the steps of the method as described above or below.

Further possible implementations or alternative solutions of the invention also encompass combinations—that are not explicitly mentioned herein—of features described above or below in regard to the embodiments. The person skilled in the art may also add individual or isolated aspects and features to the most basic form of the invention.

Other features will become apparent from the following detailed description considered in conjunction with the accompanying drawings. It is to be understood, however, that the drawings are designed solely for purposes of illustration and not as a definition of the limits, for which reference should be made to the appended claims. It should be further understood that the drawings are not drawn to scale and that they are merely intended to conceptually illustrate the structures and procedures described herein.

Further embodiments, features and advantages of the present invention will become apparent from the subsequent description and dependent claims, taken in conjunction with the accompanying drawings, in which:

FIG. 1 illustrates a first embodiment of a batch process;

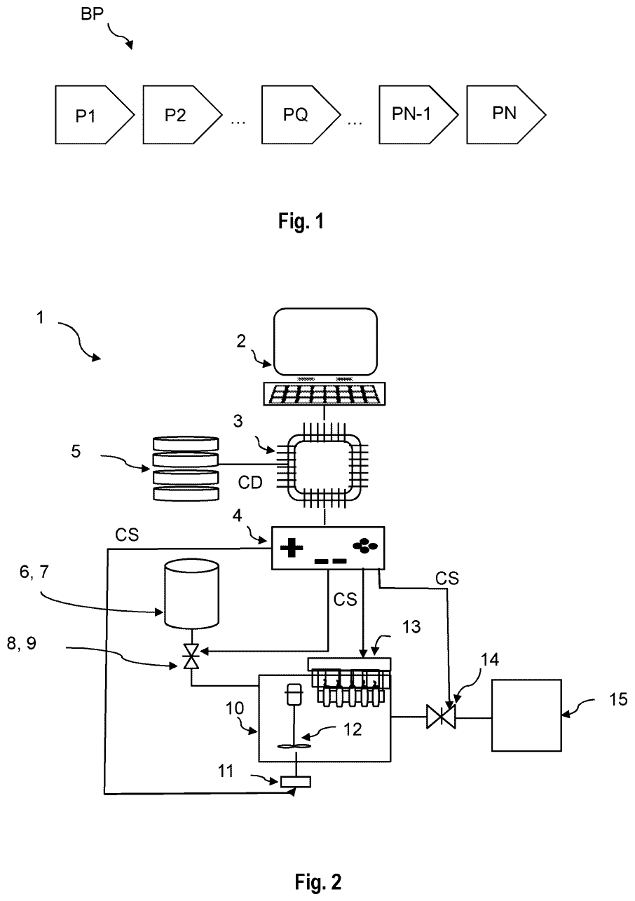

FIG. 2 shows an embodiment of a chemical plant implemented to run a batch process;

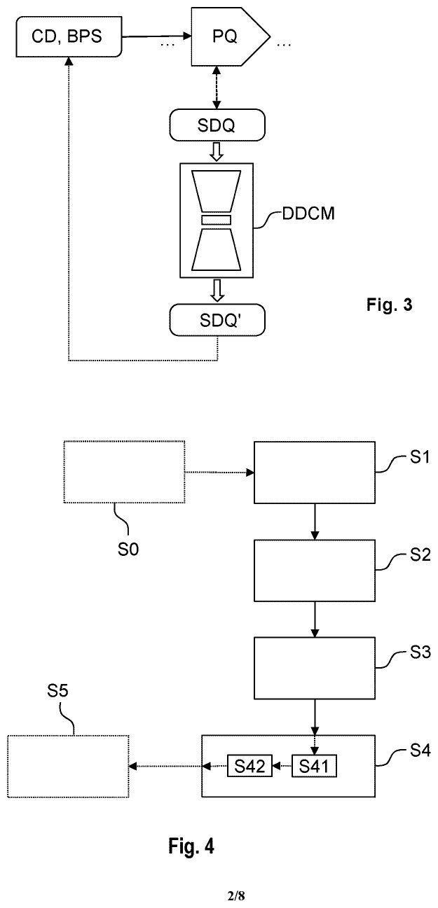

FIG. 3 illustrates aspects of a method for generating a digital representation of a batch process step;

FIG. 4 shows a flow chart of method steps involved in embodiments of the method for controlling a chemical plant;

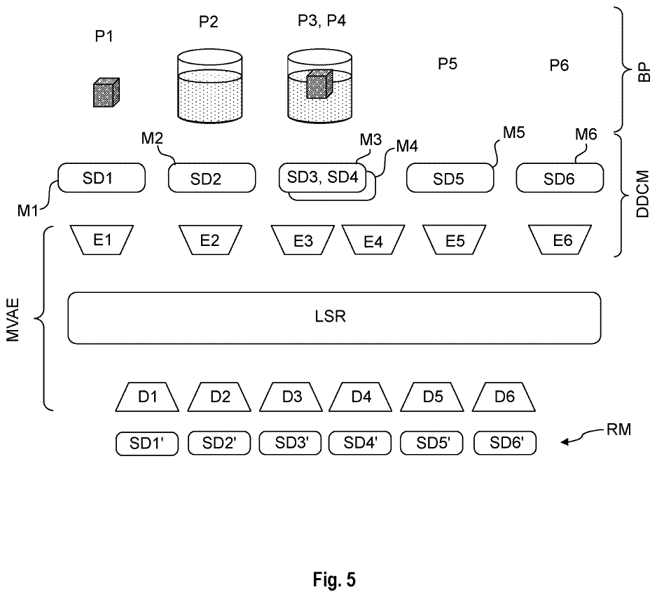

FIG. 5 illustrates an embodiment of a data driven compression model applied to a second embodiment of a batch process;

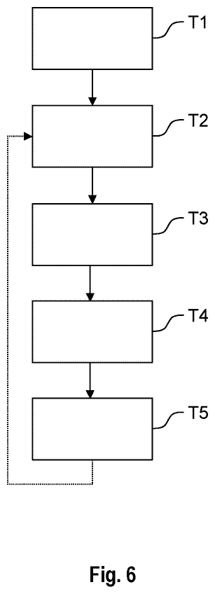

FIG. 6 shows a flow chart of method steps involved in training an MVAE;

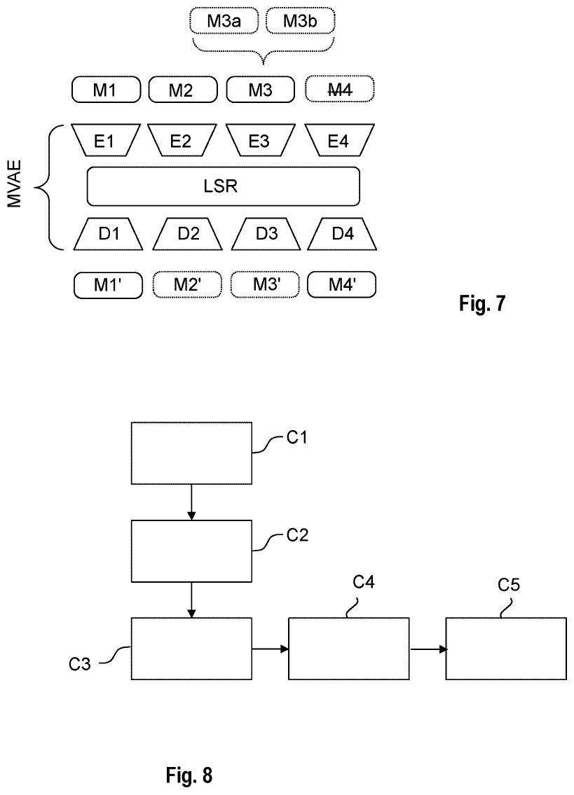

FIG. 7 illustrates embodiments of applications for an MVAE prediction in a batch process;

FIG. 8 shows a flow chart of method steps involved in evaluating MVAE applications; and

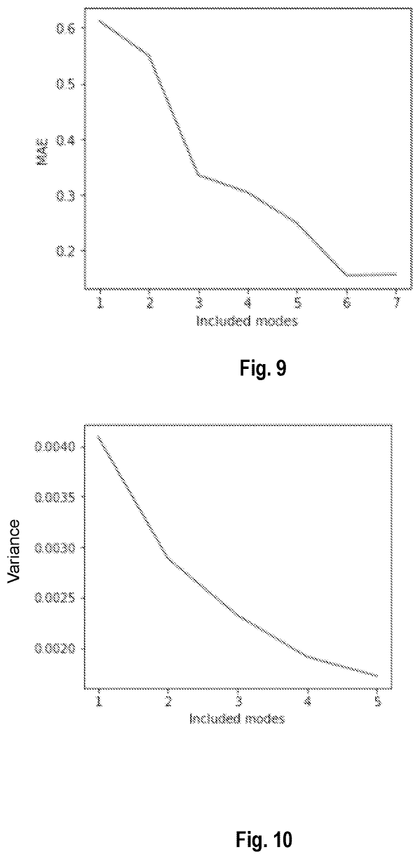

FIG. 9/10 show prediction errors of an MVAE as a function of the number of considered modes;

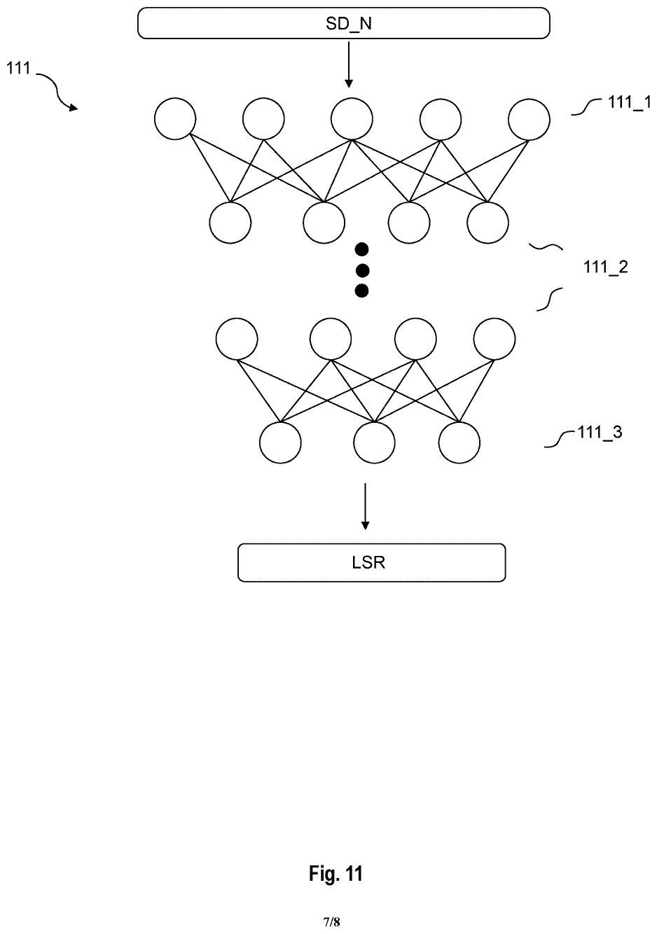

FIG. 11 shows an example of an encoder of an autoencoder.

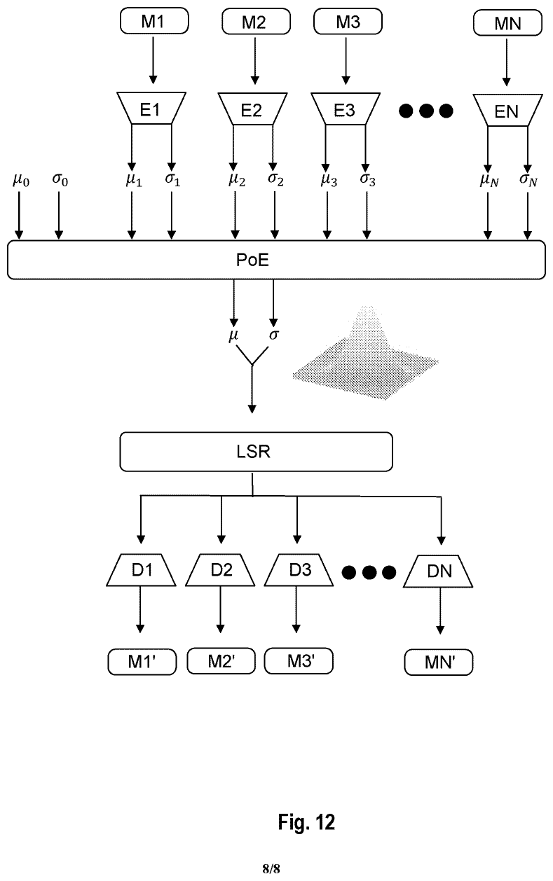

FIG. 12 shows an example of an multimodal variational autoencoder

In the Figures, like reference numerals designate like or functionally equivalent elements, unless otherwise indicated.

The following description serves to deepen the understanding and shall be understood to complement and be read together with the description as provided in the above summary section of this specification. Some aspects may have a different terminology than e.g. provided in the description above. The skilled person will nevertheless understand that those terms refer to the same subject-matter, e.g. by being more specific.

In FIGS. 1, 2 and 3 a batch process, a chemical plant implemented to carry our a batch process and an aspect for generating a control signal are illustrated.

FIG. 1 illustrates a first embodiment of a batch process BP. In the batch process BP of FIG. 1, a plurality of batch process steps P1-PN are executed. The batch process steps P1-PN refer to a series of operations that are carried out over a period of time on process units of a chemical plant. Each of the batch process steps P1-PN can be characterized by batch process step specifications. A batch process step specification may, for example, include a set of parameters identifying or characterizing a starting product in step P1. The respective batch process step specification can be considered required values for sensor data that are generated, for example, by measurement sensors or sensors identifying the basic or starting product. The entirety of all batch process step specifications form the batch process specification BPS. A batch process can result in synthesizing a chemical substance as, for example, a polymer.

FIG. 2 shows a chemical plant in terms of a system 1 for producing a chemical product in by a batch process being controlled according to the above and below depicted aspects and embodiments of methods and apparatuses for generating control data CD. In this example, the system 1 is implemented to synthesize a polymer according to a synthesis specification that is can be equivalent to a batch process specification of FIG. 1. The plant or system 1 comprises a user interface 2 and a processor 3, associated with a control unit 4, the control unit 4 is configured to receive control data CD generated according to this disclosure. For example, synthesizing a specific polymer requires the batch process steps P1-PN illustrated in FIG. 1. In this example, control data CD parametrizing the batch process steps are provided from a data base 5, in other examples, the control data CD may be provided from a server. The control unit 4 generates commands and/or control signals CS such that the batch process is carried out according to the respective batch process specification and the respective process parameters. In FIG. 2 control signals are all labeled CS.

Vessels 6, 7 each contain a component or ingredient of the chemical product to be produced or synthesized. In general, more than two vessels may be present. For illustration purposes the example only shows two vessels 6, 7 storing chemical components. Valves 8, 9 are associated with vessels 6, 7. Valves 8, 9 may be controlled to dose appropriate amounts of each component stored in the vessels 6, 7 as an ingredient for synthesizing a polymer into a reactor 10, according to a synthesis specification. A motor 11 associated to a mixer 12 may also be controlled by the control unit 4 as a function of the control data CD and control signals CS, respectively. An optional heater 13 may also be controlled by suitable control signals CS according to the synthesis and/or batch process specification BPS. The control data CD are generated to comply with the batch process specification BPS. Finally, an exit valve 14 being in fluid communication with the reactor 10 may be controlled by the control unit 4 to provide the chemical product into a container 15 or test system.

Control data CD is generated to fulfill the batch process specification BPS, however can be adapted if the batch process is transferred to another plant or during execution of the process, e.g. to increase its efficiency or performance. An example focusing on one batch process step PQ is illustrated in FIG. 3. The present disclosure, in particular, provides digital representations of characteristics of batch process steps. It is understood that a respective batch process step PQ can be characterized by sensor data SDQ. It is understood that sensor data is not strictly data that is obtained in a measurement process or from a sensor device. However, in embodiments, sensor data refers to data obtained by a physicochemical measurement process. One may contemplate of sensor data SDQ characterizing the batch process step PQ as the combination of temperature, volume and pressure values in a reactor tank.

In the following, such a set of sensor data characterizing such a batch process step PQ is also called a modality or mode data in the context of an artificial intelligence-based autoencoder. The sensor data SDQ are processed according to a data-driven compression model DDCM. This results in a digital representation SDQ′ of the received sensor data SDQ. The data-driven compression model is, for example, implemented as an artificial neural network (ANN) in terms of a multimodal variational autoencoder (MVAE). One modality of such MVAE is associated with the process step PQ and its characterizing sensor data SDQ.

In FIG. 3 the digital representation SDQ plant is a latent space representation of the sensor data SDQ within the model DDCM. The data-driven model outputs reconstructed sensor data SDQ′ that refer to the same process step PQ. One separated between feature space for the real sensor data SDQ and reconstructed or reconstruction space for the reconstructed sensor data SDQ′. Indicated by the dashed arrow, the digital representation is used to generate control data CD and/or to alter the batch process specification BPS through the reconstructed sensor data SDQ′. For example, if the batch process step PQ is associated with operating the heater 13 as shown in FIG. 2, temperature data can be used as sensor data SDQ. Generally, the sensor data are not a scalar, but multi-dimensional data. For example, a temperature field or temperature distribution within the reactor 10 can constitute the sensor data SDQ. In the latent space or compressed digital representation resulting in the SDQ′, certain aspects regarding the quality or a performance of the process step PQ, e.g., the heater or temperature variation within the reactor 10 are determined or calculated when the control data CD are translated by the control unit 4 into a respective control signal CS for the heater 13. In the example of FIG. 3, one modality Q is depicted. However, when controlling a chemical plant, all batch process step specifications and batch process steps are preferably considered through their associated sensor data when controlling the respective plant or system.

FIG. 4 shows a flowchart of method steps involved in another embodiment of the method for controlling a chemical plant, for example the chemical plant of a system depicted in FIG. 2.

It is understood that the chemical plant is implemented to carry out a batch process according to a batch process specification BPS. This can be realized in terms of a sequence of batch process steps as shown in FIG. 1. First, in step S0, sensor data is generated by measuring process parameters and/or retrieving descriptive parameters of chemical ingredients, substances and/or basic products or intermediate products of the batch process. All sensor data are clustered into clusters wherein each cluster corresponds to a specific batch process step P1-PN. FIG. 3 illustrates one cluster of sensor data SDQ relating to batch process step PQ.

Next, in step S1, the respective sensor data sets associated with the respective process steps are received, e.g. by a data processing device. Each process step has associated sensor data as for process step PQ depicted in FIG. 3.

Each sensor data set associated to the respective batch process step is processed through a data-driven compression model in step S2. The data-driven compression model DDCM is implemented as a multimodal variational autoencoder MVAE as explained in more detail regarding the following embodiments below. As a result, a compressed digital representation of the sensor data is obtained in a latent space. The MVAE and its latent space includes knowledge on the entire batch process, e.g. due to a prior learning procedure. Thus, this compressed digital representation allows to reconstruct reconstructed sensor data for the various modalities or batch process steps, in particular following process steps not yet measured. FIG. 3 shows the reconstructed sensor data SDQ′ for the Qth modality or mode identified with batch process step PQ.

In step S3, a quality measure or performance indicator with respect to the batch process step or steps is calculated deploying the data-driven compression model of step S2 and the received sensor data of step S1. The quality measure may be indicative of a physicochemical quality of an intermediate product or substance involved the batch process. For example, the viscosity of an intermediate product can be considered a quality measure. A desired property of the end-product can be considered a quality measure as well. One may derive a key performance indicator (KPI) during the batch process based on reconstructed sensor data SDQ′. If a deviation from a target KPI occurs, tentative sensor data specifying a desired working point is generated by the data-driven compression model and checked if bringing the batch process towards a desired working point is feasible. Corresponding control data is then generated as explained below. A KPI may also refer to an intermediate product instead of to the entire batch process.

Next, in step S4, control data for operating the chemical plant to be implemented to run the batch process is generated or existing control data is altered. The control data CD is generated as a function of the quality measure, as for example the viscosity. Generating the control data in a step S4 may involve the step S41 of setting a target quality measure, i.e., a viscosity value. In step S42, the quality measure is compared with the target quality measure. As a result of the steps S1-S4, control data is obtained, that may be stored in a computer-readable form for a processing unit and/or control unit of a chemical system. The control data is, for example, stored in a memory or directly executed so that a chemical plant operates accordingly. Preferably, the target quality measure is met by the batch process then. The control data is, for example, provided as a cloud service and can be retrieved from control units in various locations.

In a step S5, the control data CD is used to operate the chemical plant in more efficient manner. The control data CD may specify improved operating conditions, e.g. working points, temperatures, pressures, flows or other technical parameters, with respect to operating conditions according to the sensor data received in step S1.

Next, further embodiments for operating chemical plants are presented. FIG. 5 illustrates an embodiment of a data-driven compression model applied to another embodiment of a batch process BP. FIG. 5 shows a simplified batch process BP used to produce a selective catalytic reduction catalyst for a Diesel particle filter. This is shown in the first row of FIG. 5. The simplified batch process includes six process steps P1-P6. Selective catalytic reduction (SCR) on a filter structure reduces NOx to nitrogen and water and is used to control Diesel engine emissions. An SCR on a filter element is obtained by providing a substrate in terms of a form body in step P1 the form body may be a ceramic body as a substrate. In batch process step P2, a slurry is provided, wherein the slurry is an emulsion including zeolite particles. The body illustrated in step P1 is then coated in batch processing steps P3 and P4 using two different coatings. The analytic properties of the obtained wash coat characterize the calcination step P5. As a result, a ceramic-based catalytic body with an SCR material is obtained as illustrated by batch process step P6, wherein the SCR on filter has a specific back pressure when operated and used in an exhaust stream.

Each batch process step P1-P6 has an associated set of sensor data SD1-SD6. For example, the sensor data for the substrate according to process step P1 include P variables for characterizing the used ceramic body. The slurry used in batch process step P2 can be characterized by Q variables, e.g. about twenty, that are considered sensor data SD2. The two coating processes P3 and P4 each have R variables for each coat and sensor data SD3, SD4 respectively. R may be less than Q. The wash coat analytics associated with step P4 contain S, for example, between ten and twenty variables as sensor data SD5. Finally, the SCR on filter is characterized by the back pressure under predetermined circumstances as sensor data SD6.

The sensor data SD1-SD6 are each regarded modalities M1-M6 in terms of a multimodal variational encoder MVAE environment. Encoders E1-E6 each map the sensor data sets SD1-SD6 per modality into a latent space representation which is a compressed digital representation LSR of the input mode data M1-M6. The MVAE includes decoders D1-D6 that are implemented to reconstruct the sensor data per modality or mode into reconstruction space. In terms of the MVAE, the input mode data M1-M6 constitute a feature space while the reconstructed mode data in terms of reconstructed sensor SD1′-SD6′ constitute reconstruction space RM, respectively.

The example shown in FIG. 5 is a multi-variational encoder MVAE having six modalities. The various sensor data SD1-SD6 may have different dimensionalities P, Q, R, R, S and 1 for the modalities M1, M2, M3, M4, M5 and M6, respectively. Regardless of the different dimensionalities P, Q, R, R, S, 1 all corresponding encoders E1-E6 project in a latent space of same dimensionality which is then aggregated into the resulting LSR of the MVAE. The MVAE is or comprises an artificial neural network with weights and connections that are preset in a training method.

The example of FIG. 5 depicts a batch process implemented on a chemical plant. In the first step P1 a starting product or substrate is characterized. For example. sensor data or batch process parameters associated with P1 may be a chemical composition, e.g. measured or measurable using e.g. a spectrometer as a sensor, an identifier of the product, e.g. obtained or obtainable by a camera as a sensor, a weight of the product, e.g. obtained by weighing using e.g. a balance as a sensor. In the second step P2 a slurry is provided. For example, sensor data or batch process parameters associated with P2 may be a concentration or solid content, which may be measured e.g. by a hydrometer or by drying and weighing the residue, a particle size distribution, which may be measured e.g. by a laser diffractometer, a viscosity, which may be measured by a viscometer, a density, a pH-value, a temperature, and/or a flowability. Similarly, the coating steps P3 and P4 and the calcination step S5 can be similarly characterized by associated sensor data or batch process parameters. In step S6 the end product is characterized, wherein e.g. the back-pressure may be regarded as a target variable or quality measure.

An MVAE is first trained on (essentially) full data sets, i.e. data sets in which (essentially) all batch process parameters including the target variable having been measured or determined, which hence may be considered sensor data. The measured or determined batch process parameters or sensor data shown as SD1-SD6 are associated with their respective process step P1-P6 and with the modes M1 to M6 of the MVAE. Training may be unsupervised. Training of the MVAE may be performed by the MVAE encoding SD1-SD6 into the compressed digital representation LSR and decoding or reconstructing them as SD1′-SD6′ from the LSR and minimizing the difference between SD1-SD6 and SD1′-SD6′. During training weights of nodes in neural networks present in the encoders and decoders may be determined, which may later be used for encoding or decoding the LSR. To train the model more specifically to decode or generate SD1′-SD6′ in case not all of SD1-SD6 are available, some modes may be blocked for part of the training, e.g. not all of SD1-SD6 is used.

The MVAE may be trained using a loss function, with added components to handle the multiple modalities. The loss function may include a reconstruction loss for each modality and may comprise a Kullback-Leibler (KL) divergence term.

In context of the MVAE the encoder part comprising (sub-)encoders E1-E6 of the MVAE may be considered a data-driven model and the decoder part comprising (sub-)decoders D1-D6 may be considered a second data-driven model. The encoder part having been trained to generate a compressed digital representation LSR of (i) a quality measure indicative of a physicochemical quality of the chemical product to be produced by the plant (and (ii) the batch process step parameters of the six process steps, wherein the quality measure is included in as a batch process parameter in the sixth process step. The decoder part having been trained for the opposite direction.

Then during production, e.g. after measuring only the batch process parameters of the first process step P1 and obtaining sensor data S1, the encoder part of the MVAE may be used to encode the sensor data S1 into LSR and the decoder part of the MVAE may be used to decode the process parameters for the remaining batch process steps P2 to P6, so including the quality measure in P6. The same may be repeated e.g. after obtaining sensor data S1 and S2 for the first two process steps or after obtaining S1 and S3, for instance if S2 is for some reason unavailable. The reconstructed or generated batch process parameters SD2′ to Sd6′ may be output directly as plant operation data or further processed e.g. to provide specific instructions of how to adjust future batch process steps. In this way the batch process can be reliably monitored and controlled even at an early stage of the production.

A generic method for training an mvae is depicted in FIG. 6.

Training the MVAE involves the use of training data, but can be, for example, ground truth data for the respective batch process BP. In training step T1, training data that corresponds to the sensor data SD1-SD6 shown in FIG. 5 is generated. Generating the training data may involve monitoring a batch process corresponding to the batch process specification and collecting sensor data as depicted with respect to the modes M1-M6 in FIG. 5. The training data is provided in the feature space.

Encoders, decoders and autoencoders as presented herein can be implemented according to M. Wu, N. Goodman: “Multimodal Generative Models for Scalable Weakly-Supervised Learning”, arXiv: 1802.05335, and citations therein, which is hereby incorporated by reference.

Next, in training step T2, the encoders E1-E6 receive the respective input mode training data per mode. In training step T3, the latent space data, i.e., the digital representation of the entirety of the mode data is generated in the latent space LSR. The encoders E1-E6 may include layers that are characterized by weights and measurement operations according to the type of neural network used. Weights and other parameters of the encoder and eventually the described decoders are optimized during the training method. The latent space representation of the sensor data usually has a lower dimensionality of the entirety of the modes.

In training step S4, the decoders D1-D6 are used to reconstruct the modes in reconstruction space RM. There is usually a loss involved when the process of encoding and decoding occurs. Hence, the reconstructed sensor data sets SD1′-SD6′ may not be accurate with respect to the input sensor data sets SD1-SD6. By comparing the input and output data, a loss function indicating the similarity degree between the input and output data is calculated in training step T5.

The calculated loss function is indicative of how well the neural network or MVAE performs the mapping from input (feature) to output (reconstruction) space. The smaller the loss function, the better is the MVAE performance. During several training runs, the multimodal encoder weights or decoder weights are adapted to minimize the loss function. This is indicated by the dashed arrow so that training steps T2-T5 are repeatedly executed. Once an acceptable loss is obtained, the MVAE can be used for the specific purpose, i.e. the batch process specification based on which the MVAE was trained. The MVAE allows for a variety of applications in connection with controlling a plant implementing a respective batch process. It is noted that a variety of training algorithms and MVAE types can be used according to the known art.

In the following, examples for the use or applications of an MVAE for controlling a chemical plant are depicted. FIG. 7 illustrates embodiments of applications for an MVAE to predict batch process step parameters, sensor data and/or quality or performance indicators involved in batch processes. As an example, in FIG. 7, an MVAE having four modalities is shown. Encoders E1-E4 receive mode data M1-M4, generate the latent space representation LSR, i.e., the compressed digital representation of sensor data included in the modes M1-M4, and decoders D1-D4 generate reconstructed mode data M1′-M4′. As in the previous examples, the modes or modalities M1-M4 correspond to batch process steps.

It is an advantage of the MVAE, that even using only incomplete input mode data, reasonable and reliable reconstructed mode data for a mode is available. For example, as indicated by the dashed representation of mode M4, sensor data only for the first three batch process steps in terms of M1, M2, M3 is available. Nevertheless, the MVAE outputs reconstructed mode data M1′, M2′, M3′ and M4′. Thus, the MVAE allows for predicting sensor data in terms of reconstructed sensor data for the target mode M4. That is, in batch processes, one can predict the outcome or parameters for the last batch process step M4 based on mode data M1, M2, M3, i.e., the first three batch process steps.

A plant drivers is able to predict target KPIs based on information of the first step (the first mode M1). An uncertainty may be relatively high. However, having the batch passed more and more steps (modes M2, M2, M3) the prediction becomes more and more accurate and more precise. Between the steps (modes) it is possible to react on predictions that are above or below a threshold of a chosen KPI. The plant drivers may run a simulation how the parameters of the modes that the batch has not passed yet need to be set in order to move the KPI prediction towards a desired specification range. Based on the existing information and the target KPI range, the decoders D1-D4 reconstruct plant parameters, and the plant drivers could plausibilize if this are valid plant states. To this end, the reconstructed data is output on a display (not shown).

Another application refers to predicting the consequences of a process modification. For example, as indicated by the dotted modes M3a, M3b, alternative method steps M3aand M3b replace the third method step corresponding to M3. Adding or removing a mode can be flexibly achieved in terms of the MVAE, in particular, if modes are trained in an independent fashion. The presented digital representation in terms of the latent space obtained by the MVAE, the result or outcome of a batch process modification can be predicted. As a result, characteristics of modified modes/steps M2′, M3′ may be predicted and/or out into practice. Advantageously, accordingly modified batch processes may lead to less use of resources, as energy, time, waste handling or rejected goods/products.

Another application can include taking into account the location of a production plant that implements the considered batch process. One may input or use one modality for the location. That is, by changing the modality from a location in Europe to Asia or America, the expected outcome or variation in specific performances or quality can be predicted. This is, in particular, advantageous for plant operators having distributed sites to shift production from one location to another. A further application of the digital representation in terms of the LSR and MVAE is upscaling a given batch process from a laboratory scale to an industrial scale. In general, upscaling takes a lot of effort regarding time and energy resources. Deploying the suggested application of data-driven models allows a more efficient determination of new operating parameters due to the amended scale.

FIGS. 8, 9 and 10 refer to investigations of the applicant in connection with prediction capability and reliability of an MVAE. Regarding FIGS. 8-9 , a batch process representing an SCR on filter production is considered. Investigations are based on synthetic data, e.g. based on ground truth data. The results shown in FIG. 9 refer to seven generic modes and FIG. 10 refers to five modes that correspond to the ones considered in connection with the SCR production according to FIG. 5, wherein a simplified batch production process that includes five modes, namely M1, M2, a combination of M3 and M4 and M5 as shown in FIG. 5 are included. It is assumed that the target mode to be predicted is the back pressure.

FIGS. 9 and 10 show the mean absolute error (MAE) as a function of the included modes as input sensor data. The curves of FIGS. 9 and 10 are obtained along the evaluation steps illustrated in FIG. 8. In a first step C1, synthetic data as training data is obtained. For example, synthetic training data is found as ground truth data or under controllable conditions for the batch process. The results shown in FIG. 9 relate to synthetic test data that is based on a four-dimensional latent space and a seven-mode MVAE with modes no. 1-7, wherein mode no. 2 is considered the target mode. The seven mode data sets are obtained with seven non-linear decoder functions, and the MVAE is trained with each mode respectively.

Hence, the MVAE is trained so that the reconstruction loss is minimized based on the available training data (step C2).

Next, in step C3, the MVAE is used and fed with input mode data. First, only one mode, for example, sensor data indicative of the substrate (P1 in FIG. 5) is used. The reconstructed mode includes in particular mode M6 as the target mode. In the next step, two modes are provided as input data, and again the target mode is reconstructed. On the x-axis of FIGS. 9 and 10, the MAE and Variance drops including more and more modes as input sensor data. The mean absolute error MAE is obtained by averaging over the results of the used synthetic or training data.

Referring to FIG. 10, for example, inputting more modal sensor data referring to the substrate indicative of batch process steps results in a relatively high variance. Including further modes M2, M3 etc. indicative of further batch process steps of FIG. 5 reduces the variance. Including more modalities as input data for the MVAE reduces the error further.

One can see that an incomplete set of sensor data in terms of modes of the MVAE, wherein the incomplete sensor data refers to a subset of the considered batch process steps is sufficient to predict the target mode in terms of a reconstructed sensor data set. Hence, the presented methods and systems allow for predicting the influence of modifications in the batch process of several properties if the considered batch process, i.e., sensor data, that cannot be measured directly.

Investigations of the applicant show that the inclusion of additional modes in terms of sensor data indicative or descriptive for batch process steps reduce the prediction error (FIGS. 9 and 10). The presented use of a MVAE provides for flexible amendments regarding the used modes. One may relatively easily add new modes or features into the model to match the real-world batch process.

Even though the present disclosure relates to specific MVAEs as embodiments and exemplary sensor data, the concept of a compressed digital representation may be achieved by alternative data-driven models involving machine learning aspects, e.g. transformer models. Although the manufacture of SCR on filter is depicted as an embodiment for a batch process, one can contemplate of alternative batch processes, for example the synthetization of chemical substances.

FIG. 11 shows an example of an encoder of an autoencoder, implemented as a feed-forward neural network. Sensor Data SD_N is received by the input layer 111_1 comprising a number of nodes (represented as open circles). The sensor data is processed in a number of hidden layers 111_2 to the output layer 111_3 having fewer nodes than the input layer 111_1. For this, the nodes of one layer may be connected to each node of the adjacent layer(s), wherein a connection between nodes may comprise a weight value, which may be adjusted during training. The output layer 111_3 provides a compressed digital representation LSR. An example of a decoder may be the inversely structured feed-forward neurol network, wherein 111_3 would correspond to the input layer and 111_1 would correspond to the output layer.

FIG. 12 shows another example of an MVAE comprising an encoder, the encoder comprising a number of (sub-)encoders E1-EN for a corresponding number of modes M1-MN, wherein each may correspond to a respective batch process step, as e.g. described above. Each (sub-)encoder (which may be an inference network) may determine a probability distribution for the respective mode and provide characterizing values or variational parameters for this probability distribution, in this example respective means μ₁-μ_{N} and standard derivations σ₁-_{N}. The distributions may be combined into a single distribution, in this example by a product-of-experts (PoE). The combination may be performed within the encoder, e.g. as a separate module of the encoder, which is operationally coupled to the (sub-) encoders M1-MN. Also, a prior probability distribution, e.g. obtained by pre-training, prior modeling or the like, may be input into the PoE. The PoE may combine the variational parameters in a principled and efficient manner. In case a mode is missing during training, which e.g. may be done intentionally to train reconstruction of missing modes, the respective encoder or inference network may be dropped. Thus, the parameters of E1-EN are shared across different combinations of missing inputs. The compressed digital representation LSR is or comprises the combined probability distribution, from which reconstructed modes M1′-MN′ may be sampled or generated through the (sub-) decoders D1-DN.

In the present specification, any presented connection in the described embodiments is to be understood in a way that the involved components are operationally coupled. Thus, the connections can be direct or indirect with any number or combination of intervening elements, and there may be merely a functional relationship between the components.

Moreover, any of the methods, processes and actions described or illustrated herein may be implemented using executable instructions in a general-purpose or special-purpose processor and stored on a computer-readable storage medium (e.g., disk, memory, or the like) to be executed by such a processor. References to a ‘computer-readable storage medium’ should be understood to encompass specialized circuits such as signal processing devices, and other devices.

The expressions “A and/or B” and “at least one of: A or B” are considered interchangeable and meant to comprise any one of the following three scenarios: (i) A, (ii) B, (iii) A and B. More generally, the expression “at least one of the following: <a list of two or more elements>” and “at least one of <a list of two or more elements>” and similar wording, where the list of two or more elements are joined by “and” or “or”, mean at least any one of the elements, or at least any two or more of the elements, or at least all the elements.

The article “a” is not to be understood as “one”, i.e. use of the expression “an element” does not preclude that also further elements are present.

The term “comprising” is to be understood in an open sense, i.e. in a way that an object that “comprises an element A” may also comprise further elements in addition to element A. Further, the term “comprising” may be limited to “consisting of”, i.e. consisting of only the specified elements.

It will be understood that all presented embodiments are only examples, and that any feature presented for a particular example embodiment may be used with any aspect on its own or in combination with any feature presented for the same or another particular example embodiment and/or in combination with any other feature not mentioned. In particular, the example embodiments presented in this specification shall also be understood to be disclosed in all possible combinations with each other, as far as it is technically reasonable and the example embodiments are not alternatives with respect to each other. It will further be understood that any feature presented for an example embodiment in a particular category (method/apparatus/computer program/system) may also be used in a corresponding manner in an example embodiment of any other category. It should also be understood that presence of a feature in the presented example embodiments shall not necessarily mean that this feature forms an essential feature and cannot be omitted or substituted.

The sequence of all method steps presented above is not mandatory, also alternative sequences may be possible. Nevertheless, the specific sequence of method steps exemplarily shown in the figures shall be considered as one possible sequence of method steps for the respective embodiment described by the respective FIG.

### REFERENCE SIGNS

1 system for producing chemical substance/chemical plant
2 interface
3 processor
4 data base
5 control unit
6,7 vessel
8,9 valve
10 reactor
11 motor
12 mixer
13 heater
14 exit valve
15 tank
BP batch process
BPS batch process specification
CD plant operation data/control data
CS control signal
DQ decoder for mode Q
EQ encoder for mode Q
DDCM data driven compression model
LSR latent space representation
M1-M1 mode/modality
P1-PN batch process steps
RM reconstructed modes
SDQ sensor data associated with process step PQ
SDQ′ reconstructed sensor data
S0 Generating sensor data
S1 Receiving sensor data
S2 applying data driven compression model
S3 determining quality measure/performance indicator
S4 generating control data
S41 setting a target quality measure
S42 comparing quality measure/performance indicator with target
S5 operating the chemical plant
T1 generating training data
T2 inputting input mode training data
T3 generating latent data
T4 reconstructing reconstructed mode data
T5 adapting encoder/decoder parameters for reducing reconstruction loss (loss function)
C1 training for minimizing reconstruction loss
C2 taking samples from a latent space distribution
C3 reconstructing target mode
C4 averaging over distribution
C5 determining mean absolute error (MAE)

1. A method for operating a chemical plant implemented to run a batch process for producing a chemical product, wherein the batch process includes a plurality of process steps, the method comprising:
receiving sensor data associated with at least one process step of the batch process
processing the sensor data according to a data driven model for generating a compressed digital representation of the sensor data associated with the at least one process step;
determining a quality measure indicative of a physicochemical quality of the chemical product to be produced by the plant and/or a performance indicator of the batch process as a function of the digital representation of the received sensor data; generating plant operation data indicative for operating the chemical plant based on the determined quality measure and/or the determined performance indicator; and outputting plant operation data.

2. The method according to claim 1, each process step being associated with a set of batch process step parameters, and the sensor data corresponding to at least one batch process parameter associated with the at least one process step, wherein processing the sensor data according to the data driven model for generating a compressed digital representation comprises;
obtaining the compressed digital representation of the sensor data associated with the at least one process step using the data-driven model, the data driven model having been trained to generate a compressed digital representation of (i) a quality measure indicative of a physicochemical quality of the chemical product to be produced by the plant and/or a performance indicator of the batch process and (ii) the batch process step parameters of at least two process steps including said at least one process step.

3. The method according to claim 2, determining the quality measure and/or the performance indicator comprises generating the quality measure and/or the performance indicator based on the compressed digital representation using a second data driven model, the second data driven model having been trained to generate the quality measure and/or the performance indicator from the compressed digital representation of (i) the quality measure indicative of a physicochemical quality of the chemical product to be produced by the plant and/or the performance indicator of the batch process and (ii) the batch process step parameters of at least two process steps including the at least one process step; and wherein determining plant operation data is based on the generated quality measure and/or the generated performance indicator.

4. The method according to claim 2, wherein the data driven model comprises an encoder of an autoencoder, and the second data driven model comprises a decoder of the autoencoder, wherein the encoder is trained to encode (i) the quality measure indicative of a physicochemical quality of the chemical product to be produced by the plant and/or the performance indicator of the batch process and (ii) the batch process step parameters of at least two process steps including the at least one process step into the compressed digital representation and the decoder is respectively trained to decode (i) the quality measure indicative of a physicochemical quality of the chemical product to be produced by the plant and/or the performance indicator of the batch process and (ii) the batch process step parameters of at least two process steps including the at least one process step from the compressed digital representation.

5. The method according to claim 4, wherein the autoencoder is a multimodal variational autoencoder, wherein each process step of the batch process corresponds to a mode of the multimodal variational autoencoder and, in particular at least one mode corresponds to the quality measure indicative of a physicochemical quality of the chemical product to be produced by the plant and/or the performance indicator of the batch process.

6. The method according to claim 5, wherein at least one further mode corresponds to the location of the plant or a characteristic of the plant.

7. The method according to claim 3, wherein the data driven model having further been trained to generate the compressed digital representation of (i) a quality measure indicative of a physicochemical quality of the chemical product to be produced by the plant as produced by another plant and/or a performance indicator of the batch process implemented on the other plant and (ii) the batch process step parameters of at least two process steps implemented on the other plant including the at least one process step; and wherein
the second data driven model having been trained to generate the quality measure and/or the performance indicator from the compressed digital representation of (i) the quality measure indicative of a physicochemical quality of the chemical product to be produced by the plant as produced by the other plant and/or the performance indicator of the batch process implemented on the other plant and (ii) the batch process step parameters of at least two process steps implemented on the other plant including the at least one process step.

8. The method according to claim 7, wherein the batch process implemented on the plant (1) has at least one additional process step then the batch process implemented on the other plant, and wherein the method further comprises:
determining at least one process parameter of the at least one additional process step using the second data driven model; and
providing the at least one process parameter.

9. The method of claim 1, further comprising:
operating the chemical plant as a function of the plant operation data or in case the plant operation data comprises control data as a function of the control data.

10. The method of claim 1, further comprising:
comparing the quality measure and/or performance indicator with a target quality for obtaining a comparison result; and
generating control data for operating the chemical plant based on the comparison result.

11. The method of claim 1, further comprising:
Generating, based on the quality measure and/or the performance indicator, control data suitable for causing a display device to indicate at least one of a warning message to operating personnel, a list of operating conditions of the chemical plant, an alarm, or a physicochemical quality of intermediate products of the batch process.

12. The method of claim 1, wherein the received sensor data is representative of a first set of first physicochemical parameters, the method further comprising:
generating sensor data derived from the compressed digital representation of the received sensor data, wherein the generated sensor data is representative of a second set of physicochemical parameters being at least partially different from the first set.

13. The method of claim 1, wherein the data driven model is implemented to receive input mode data and to output reconstructed mode data;
wherein each batch process step of the batch process is associated to one respective mode; and
wherein said input mode data for a respective mode comprises the sensor data-(SDQ) associated to the at least one batch process step being associated to the respective mode; and
wherein the output mode data for a respective mode comprises reconstructed sensor data associated to the at least one process step being associated to the respective mode.

14. The method of claim 13, wherein the data driven model has a predetermined number of modalities corresponding to the number of batch process steps the method further comprising:
inputting input mode data for a first set of modes including a first number of modes; and
outputting reconstructed mode data for a second set of modes including a second number of modes, wherein the first number of modes is less than the second number of modes.

15. The method of claim 14, wherein the second set of modes includes at least one mode associated to a batch process step that is carried out later than the batch process steps associated with the modes of the first set of modes.

16. The method of claim 13, further comprising:
training the data driven model using training data sets generated by monitoring a plurality of variants of the batch process for generating sensor data indicative of respective batch process steps.

17. (canceled)

18. The method of claim 16, further comprising:
measuring batch process parameters indicative of physicochemical properties of ingredients in terms of sensor data and/or characteristics of the batch process steps; and
clustering said sensor data into clusters, wherein each cluster is assigned to one batch process step and/or a mode of the MVAE.

19. (canceled)

20. The method of claim 1, any further comprising:
predicting a quality measure and/or a performance indicator for a selected batch process step based on sensor data associated with another process step of the batch process, wherein the other process step precedes the selected process step; and
generating the control data as a function of the predicted quality measure and/or a performance indicator;
wherein predicting includes reconstructing sensor data associated to the selected batch process step.

21. (canceled)

22. A system for producing a chemical product comprising a control unit and controllable plant units associated to batch process steps, wherein the control unit is implemented to execute the method of claim 1.

23. (canceled)

24. An apparatus comprising at least one processor and at least one memory storing instructions that, when executed by the at least one processor, cause the apparatus at least to carry out the steps of the method according to claim 1.

25.-26. (cancele
